(19) United States
(12) Patent Application Publication
(10) Pub. No.: US 2026/0282670 A1
(43) Pub. Date: Sep. 17, 2026

(54) DISPLAY PANEL, METHOD FOR MANUFACTURING THE DISPLAY PANEL, AND ELECTRONIC DEVICE HAVING THE DISPLAY PANEL

(71) Applicant: Samsung Display Co., LTD., Yongin-si (KR)

(72) Inventors: SEUNGBAE KANG, Yongin-si (KR); SUKYEONG SHIN, Yongin-si (KR); WOOJIN CHO, Yongin-si (KR)

(21) Appl. No.: 19/549,283

(22) Filed: Feb. 25, 2026

(30) Foreign Application Priority Data
Mar. 12, 2025 (KR) 10-2025-0031866

(51) Int. Cl. H10K 59/124; H10K 59/12; H10K 59/123

(52) U.S. Cl. CPC H10K 59/124; H10K 59/1201; H10K 59/123

(57) ABSTRACT

A display panel includes a circuit layer, a planarized circuit insulating layer, a groove circuit insulating layer, a groove formation unit and an anode electrode. The circuit layer includes a transistor. The planarized circuit insulating layer is disposed on the circuit layer and has a lower contact hole defined therein. The groove circuit insulating layer is disposed on the planarized circuit insulating layer and has an upper contact hole and a groove opening defined therein. The upper contact hole overlaps with the lower contact hole. The groove opening exposes a portion of an upper surface of the planarized circuit insulating layer. The groove formation unit is disposed in the groove opening. The anode electrode covers at least a portion of the groove circuit insulating layer and the groove formation unit, has at least a portion disposed in the lower contact hole, and is electrically connected to the transistor.

This application claims priority to Korean Patent Application No. 10-2025-0031866, filed on Mar. 12, 2025, and all the benefits accruing therefrom under 35 U.S.C. §119, the content of which in its entirety is herein incorporated by reference.

### BACKGROUND

### 1. Field

The present disclosure relates to a display panel, a method of manufacturing a display panel and an electronic device including the display panel. More particularly, the present disclosure relates to a display panel having improved luminance and color reproduction of light emitted in a direction different than towards a front of the display panel through the incorporation of a grooved anode electrode, a manufacturing method of the display panel, and an electronic device including the display panel.

### 2. Description of the Related Art

There may be a difference in front light emitted from the front of a display panel and side light emitted from a direction other than the front of the display panel. For example, luminance of the front light may be greater than luminance of side light. In some aspects, color of light observed from the front of the display panel may differ from the color of light observed at an angle.

Accordingly, the following phenomenon may occur for a case in which a display panel is viewed in a direction other than the front of the display panel. Since light emitted from a side of the display panel may have a lower luminance than light emitted from the front of the display panel, the light emitted from the side may be observed as being darker. The color the light emitted from the side may differ from the light emitted from the front, and color reproduction in an area where the light emitted from the side may be reduced.

### SUMMARY

The present disclosure is to resolve the above problems and relates to a display panel with formation of an anode electrode having a groove by a grooved circuit insulating layer and a groove formation unit, a manufacturing method for the display panel, and an electronic device including the display panel.

The present disclosure relates to a display panel with increased luminance of light emitted in a direction other than the front by having a grooved anode electrode, a manufacturing method for the display panel, and an electronic device including the display panel.

The present disclosure relates to a display panel with reduced wavelength difference and color difference between light emitted front and light emitted in another direction by having a grooved anode electrode, a manufacturing method for the display panel, and an electronic device including the display panel.

The present disclosure relates to a display panel supportive of easier formation of a grooved anode electrode, a manufacturing method for the display panel, and an electronic device including the display panel.

A display panel according to an embodiment of the present disclosure may include a base member, a circuit layer, a planarized circuit insulating layer, a groove circuit insulating layer, a groove formation unit, an anode electrode, a light-emission layer and a cathode electrode. The circuit layer may be disposed on the base member and include a transistor. The planarized circuit insulating layer may be disposed on the circuit layer and have a lower contact hole defined in the planarized circuit insulating layer. The groove circuit insulating layer may be disposed on the planarized circuit insulating layer and have an upper contact hole and a groove opening defined in the groove circuit insulating layer. The upper contact hole may overlap with the lower contact hole. The groove opening may expose a portion of an upper surface of the planarized circuit insulating layer. The groove formation unit may be disposed in the groove opening. The anode electrode may cover the groove formation unit and at least a portion of the groove circuit insulating layer, have at least a portion disposed in the lower contact hole and be electrically connected to the transistor. The light-emission layer may be disposed on the anode electrode. The cathode electrode may be disposed on the light-emission layer.

In an embodiment of the present disclosure, the groove circuit insulating layer may have a first height. The groove formation unit may have a second height. The second height may be smaller than the first height.

In an embodiment of the present disclosure, a width of an upper portion of the groove opening may be greater than a width of a lower portion of the groove opening. An area of the upper portion of the groove formation unit may be smaller than an area of the lower portion of the groove formation unit.

In an embodiment, a distance between a portion of an upper surface of the anode electrode overlapping with the groove circuit insulating layer and an upper surface of the planarized circuit insulating layer may be a first distance. A distance between a portion of the upper surface of the anode electrode overlapping with the groove formation unit and the upper surface of the planarized circuit insulating layer may be a second distance. The first distance may be greater than the second distance.

In an embodiment of the present disclosure, a distance between a portion of the upper surface of the anode electrode not overlapping with the groove circuit insulating layer and the groove formation unit and the upper surface of the planarized circuit insulating layer may be a third distance. The third distance may be smaller than the first distance and the second distance.

In an embodiment of the present disclosure, an angle between an inner side surface of the groove circuit insulating layer having a groove opening defined therein and the upper surface of the planarized circuit insulating layer may range from 20 degrees to 80 degrees. An angle between a side surface of the groove formation unit and the upper surface of the planarized circuit insulating layer may range from 20 degrees to 80 degrees.

In an embodiment of the present disclosure, the groove formation unit may include a metal.

In an embodiment of the present disclosure, a connection unit may be further included. The connection unit may have at least a portion disposed in the lower contact hole. The connection unit may be electrically connected to the transistor.

In an embodiment of the present disclosure, the groove formation unit and the connection unit may include a metal. The groove formation unit and the connection unit may include the same material.

In an embodiment of the present disclosure, the groove circuit insulating layer may be formed through dry etching. The groove formation unit may be formed through wet etching.

In an embodiment of the present disclosure, a pixel definition film may be further included. The pixel definition film may be disposed on the groove circuit insulating layer, and a light-emission opening may be defined in the pixel definition film. The groove formation unit may overlap with the light-emission opening.

In an embodiment of the present disclosure, the groove opening may be provided in plurality. The plurality of groove openings may include a first groove opening and a second groove opening surrounding the first groove opening. The groove formation unit may be provided in plurality. The plurality of groove formation units may include a first groove formation unit disposed in the first groove opening and a second groove formation unit disposed in the second groove opening and surrounding the first groove formation unit.

In an embodiment of the present disclosure, the anode electrode may reflect at least some of incident light. The cathode electrode may transmit at least some of incident light.

A method of manufacturing a display panel according to an embodiment of the present disclosure may include preparing, disposing a planarized circuit insulating layer, forming a groove circuit insulating layer, forming a groove formation unit, disposing an anode electrode, disposing a light-emission layer and disposing a cathode electrode. In the preparing, a circuit layer including a base member and a transistor disposed on the base member may be prepared. In the disposing a planarized circuit insulating layer, a planarized circuit insulating layer may be disposed on the circuit layer. In the forming a groove circuit insulating layer, a groove circuit insulating layer may be disposed on the planarized circuit insulating layer. In the groove circuit insulating layer, a groove opening exposing a portion of an upper surface of the planarized circuit insulating layer is defined. In the forming a groove formation unit, a groove formation unit may be formed in the groove opening. In the disposing an anode electrode, an anode electrode may be disposed which covers at least some of the groove circuit insulating layer and the groove formation unit along shapes of the groove circuit insulating layer and the groove formation unit. In the disposing a light-emission layer, a light-emission layer may be disposed on the anode electrode. In the disposing a cathode electrode, a cathode electrode may be disposed on the light-emission layer.

In an embodiment of the present disclosure, the forming a groove circuit insulating layer may include disposing an etchable circuit insulating layer and first etching. In the disposing an etchable circuit insulating layer, an etchable circuit insulating layer may be disposed on the planarized circuit insulating layer. The first etching may include dry etching the etchable circuit insulating layer to form the groove circuit insulating layer.

In an embodiment of the present disclosure, the forming a groove formation unit may include disposing an etchable member and performing a second etching. In the disposing an etchable member, an etchable member may be disposed on the planarized circuit insulating layer and the groove circuit insulating layer. Performing the second etching may include wet etching the etchable member to form the groove formation unit.

In an embodiment of the present disclosure, the method may further include disposing a pixel definition film. In the disposing a pixel definition film, the pixel definition film may be disposed on the groove circuit insulating layer, and in the pixel definition film, a light-emission opening overlapping with the groove formation unit may be defined.

In an embodiment of the present disclosure, in the disposing the planarized circuit insulating layer, a lower contact hole may be defined in the planarized circuit insulating layer. In the forming the groove circuit insulating layer, an upper contact hole overlapping with the lower contact hole may be defined in the groove circuit insulating layer. In the disposing the etchable member, the etchable member may be disposed in the lower contact hole and the upper contact hole. In the second etching, the wet etching of the etchable member may further form a connection unit having at least a portion disposed in the lower contact hole and electrically connected to the transistor.

In an embodiment of the present disclosure, a height of the groove circuit insulating layer may be greater than a height of the groove formation unit.

An electronic device according to an embodiment of the present disclosure may include a base member, a circuit layer, a circuit insulating layer, a groove formation unit, an anode electrode, a light-emission layer, and a cathode electrode. The circuit layer may be disposed on the base member and include a transistor. The circuit insulating layer may be disposed on the circuit layer, may include a recessed surface and a protruding surface and may have a connection contact hole defined therein. the protruding surface may not overlap with the recessed surface. A distance between the recessed surface and the base member may be smaller than a distance between the protruding surface and the base member. The groove formation unit may be disposed on the protruding surface. The anode electrode may cover at least some of the circuit insulating layer and the groove formation unit, have at least a portion disposed in a connection contact hole, and be electrically connected to the transistor. The light-emission layer may be disposed on the anode electrode. The cathode electrode may be disposed on the light-emission layer.

According to one embodiment of the present disclosure, an object of the present disclosure is to provide a display panel having a grooved anode electrode configured to disperse incident light to increase luminance of light emitted in a direction other than the front, a manufacturing method for the display panel, and an electronic device including a display panel.

According to one embodiment of the present disclosure, an object of the present disclosure is to provide a display panel having a grooved anode electrode disposed unparallel with a cathode electrode to reduce difference in wavelength and color between light emitted front and light emitted in another direction, a manufacturing method for the display panel, and an electronic device including the display panel.

According to one embodiment of the present disclosure, an object of the present disclosure is to provide a display panel supportive of easier formation of a grooved anode electrode, a manufacturing method for the display panel, and an electronic device including the display panel.

### BRIEF DESCRIPTION OF THE DRAWINGS

These and/or other features will become apparent and more readily appreciated from the following description of the embodiments, taken in conjunction with the accompanying drawings in which:

FIG. 1 is an example illustration of a display device according to an embodiment of the present disclosure;

FIG. 2A through FIG. 2D are example cross-sectional views of a display device according to an embodiment of the present disclosure;

FIG. 3 is an example plan view of a display panel according to an embodiment of the present disclosure;

FIG. 4 is an example equivalent circuit diagram of a pixel according to an embodiment of the present disclosure;

FIG. 5 is an example illustration of a light-emission control signal Ei, and scan signals Si-1, Si, Si+1 applied to the pixel illustrated in FIG. 4;

FIG. 6 is an example cross-sectional view of a display panel according to an embodiment of the present disclosure;

FIG. 7 is an example magnified view of the AA section illustrated in FIG. 6;

FIG. 8 is an example plan view of any one of a plurality of pixels according to an embodiment of the present disclosure;

FIG. 9 is an example flow chart of a method of manufacturing a display panel according to an embodiment of the present disclosure;

FIG. 10A through FIG. 10L each is a schematic cross-sectional view of a step of a method of manufacturing a display panel according to an embodiment of the present disclosure;

FIG. 11 and FIG. 12 are example magnified views of a portion of an example cross-sectional view of a display panel according to an embodiment of the present disclosure;

FIG. 13 is an example plan view of any one of a plurality of pixels according to an embodiment of the present disclosure;

FIG. 14 is an example illustration of a block diagram of an electronic device according to an embodiment of the present disclosure; and

FIG. 15 are an example schematic diagrams of electronic devices according to various embodiments of the present disclosure.

### DETAILED DESCRIPTION

References will now be made in detail to certain embodiments, of which examples are illustrated in the accompanying drawings, where like reference numerals refer to like elements throughout. The embodiments may have a variety of forms and permutations, but the present disclosure shall by no means be construed as being limited to the described embodiments. Rather, the present disclosure shall be construed to encompass all forms, permutations, equivalents and substitutes covered by the technical ideas and scope of the present disclosure. Accordingly, the embodiments are merely described herein, by referring to the figures, to explain features of the present disclosure.

Like or identical reference numerals refer to like or identical elements. Moreover, in the accompanying drawings, the thicknesses, ratios, and dimensions of the elements may not be to exact scale and may have been exaggerated for the benefit of effective explanation of the technical features associated with these elements. As such, the present disclosure shall not be restricted to the thicknesses, ratios, dimensions, and the like illustrated in the drawings.

Terms such as, for example, first, second, and the like may be used to describe various components, but the components should not be limited by the terms. The terms as used herein may distinguish one component from other components and are not to be limited by the terms. For example, without departing the scope of the present disclosure, a first component may be referred to as a second component, and similarly, the second component may also be referred to as the first component. The terms of a singular form may include plural forms unless otherwise specified.

The terminology used herein is for the purpose of describing particular embodiments and is not intended to be limiting. As used herein, “a,” “an,” “the,” and “at least one” do not denote a limitation of quantity, and are intended to include both the singular and plural, unless the context clearly indicates otherwise. For example, “an element” has the same meaning as “at least one element," unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, or components.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

Embodiments are described herein with reference to cross section illustrations that are schematic illustrations of example embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

It should be appreciated that various embodiments of the disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. It is to be understood that a singular form of a noun corresponding to an item may include one or more of the items, unless the relevant context clearly indicates otherwise. As used herein, each of such phrases as "A or B”, "at least one of A and B”, "at least one of A or B”, "A, B, or C”, "at least one of A, B, and C”, and "at least one of A, B, or C”, may include any one of, or all possible combinations of the items enumerated together in a corresponding one of the phrases.

An expression such as “comprising” or “including” is intended to designate a characteristic, a number, a step, an operation, an element, a part or combinations thereof, and shall not be construed to preclude any possibility of presence or addition of one or more other characteristics, numbers, steps, operations, elements, parts or combinations thereof.

A display device according to an embodiment may be applicable to various electronic devices. An electronic device according to an embodiment may include the described display device and further include a module or a device having an additional function in addition to the display device.

The term “overlapping” refers to disposition on a normal direction of a surface of a component without being limited to disposition on or below the surface.

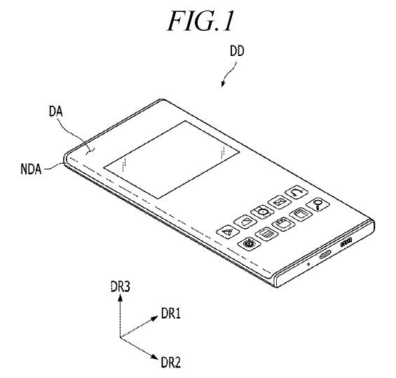

FIG. 1 is an example illustration of a display device DD according to an embodiment of the present disclosure.

In FIG. 1, a smartphone is exemplarily illustrated as the display device DD. However, a use of the display device DD is not limited thereto.

The display device DD may have a display area DA and a non-display area NDA defined therein. The display area DA may be configured to display an image and detect an input of a user.

At least a portion of the display region DA may be parallel to a plane defined by a first directional axis DR1 and a second directional axis DR2. A normal direction of the display region DA, i.e., a thickness direction of the display device DD, may be directed by a third directional axis DR3. A front surface (or an upper surface) and a back surface (or a lower surface) of each member may be distinguished by the third directional axis DR3. However, directions pointed by the first through the third directional axes DR1, DR2 and DR3 are merely a relative concept and may be converted into other directions. Hereinafter, a first through a third directions DR1, DR2 and DR3 are directions pointed by the first through the third directional axes DR1, DR2 and DR3, respectively, and described with the same figure references.

A shape of the display region DA illustrated in FIG. 1 is an example and may be modified as applicable or desired without limitation.

The non-display region NDA may be a region adjacent to the display region DA and a region that does not display an image. A bezel region of the display device DD may be defined by the non-display region NDA. The display region DA may be surrounded by the non-display region NDA. Yet, a shape of the non-display region NDA is not limited to the above. A shape of the display region DA and a shape of the non-display region NDA may be modified.

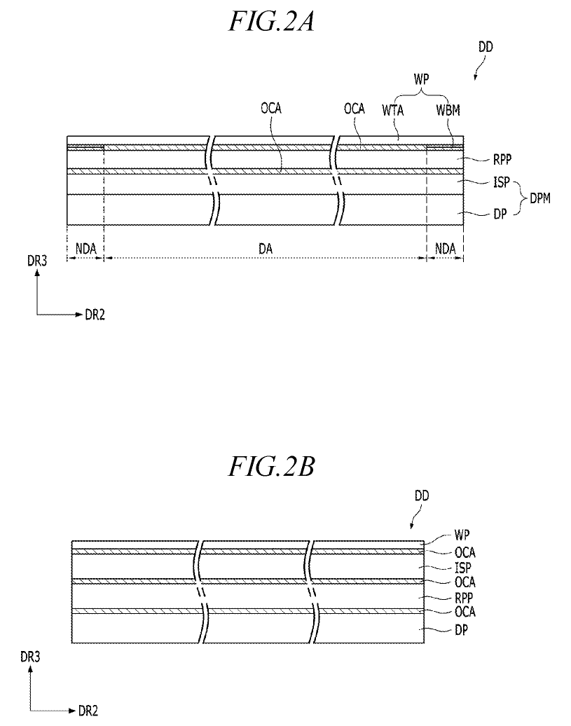

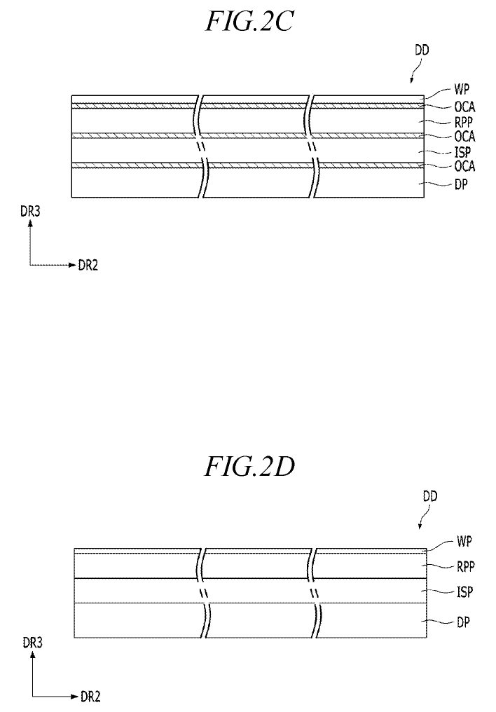

FIGS. 2A through 2D are example cross-sectional views of a display device DD according to an embodiment of the present disclosure.

FIGS. 2A through 2D illustrate a cross-section defined by the second directional axis DR2 and the third directional axis DR3. FIGS. 2A through 2D are simplified to describe lamination relationships among functional panels and/or functional members composing the display device DD illustrated in FIGS. 2A through 2D.

Referring to FIG. 2A, the display device DD may include a display module DPM, a reflection protection member RPP, a window member WP, and a plurality of adhesive units OCA.

The display module DPM may include a display panel DP and an input sensor unit ISP. The display module DPM may be configured to emit light and detect an input. A base member may be further disposed below the display module DPM.

The display panel DP may be configured to emit light. The display panel DP may be a light-emitting display panel. The display panel DP may be an organic light-emitting display panel, a quantum dot light-emitting display panel or a micro light-emitting display panel.

The input sensor unit ISP may be disposed on the display panel DP. The input sensor unit ISP may be configured to obtain coordination information of an external input. Particularly at least one of a capacitance type input sensor, a resistance film type input sensor, an optical sensor, an electromagnetic resonance type input sensor, an ultrasonic type input sensor and an infrared wave type input sensor may be used as the input sensor unit ISP.

The reflection protection member RPP may be disposed on the display module DPM. In some aspects, the reflection protection member RPP may be configured to reduce light reflectivity of external light incident from an upper side of the window member WP. According to one embodiment of the present disclosure, the reflection protection member RPP may include a retarder, a polarizer and a plurality of color filters.

The window member WP may be disposed on the reflection protection member RPP. The window member WP may include a light penetration part WTA and a light block part WBM.

The light penetration part WTA may include glass and/or a synthetic resin. The light penetration part WTA is not limited to a single layer. The light penetration part WTA may include two or more films attached by an adhesive member. At least a portion of the light penetration part WTA may overlap with the display region DA of the display device DD.

The light block part WBM may partially overlap with the light penetration part WTA. The light block part WBM may be disposed below the light penetration part WTA and overlap with the non-display region NDA of the display device DD.

The plurality of adhesive members OCA may be optically transparent adhesive members. The plurality of adhesive members OCA may each be disposed between a below member and an upper member and configured to attach the below member and the upper member.

A portion of the plurality of adhesive members OCA may be disposed between the display module DPM and the reflection protection member RPP. The other portion of the plurality of adhesive members OCA may be disposed between the reflection protection member RPP and the window member WP.

A position of the plurality of adhesive members OCA is not limited to the above. The plurality of adhesive members OCA may be also disposed between the display panel DP and the input sensor unit ISP. In some aspects, at least some of the plurality of adhesive members OCA may be omitted.

Referring to FIG. 2B, the display device DD may include a display panel DP, a reflection protection member RPP, an input sensor unit ISP and a window member WP.

A portion of the plurality of adhesive members OCA may be disposed between the display panel DP and the reflection protection member RPP. Another portion of the plurality of adhesive members OCA may be disposed between the reflection protection member RPP and the input sensor unit ISP. Yet another portion of the plurality of adhesive members OCA may be disposed between the input sensor unit ISP and the window member WP.

Referring to FIG. 2C, in the lamination structure illustrated in FIG. 2B, positions of the reflection protection member RPP and the input sensor unit ISP may be switched.

Referring to FIG. 2D, the plurality of adhesive members OCA may be omitted in the display device DD, and the display panel DP, the input sensor unit ISP, the reflection protection member RPP and the window member WP may be successively laminated. In another embodiment of the present disclosure, a lamination order of the input sensor unit ISP and the reflection protection member RPP may be switched.

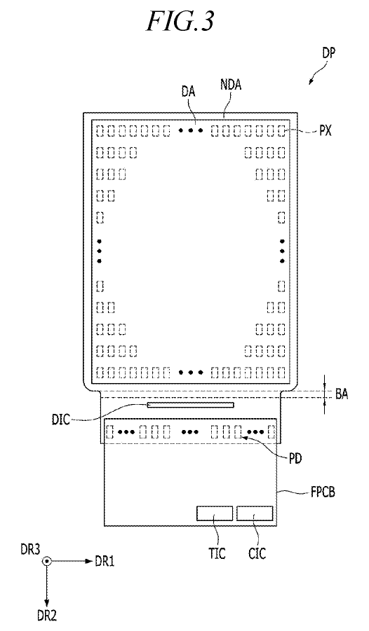

FIG. 3 is an example illustration of a plan view of a display panel DP according to an embodiment of the present disclosure.

Referring to FIG. 3, the display panel DP may have a display region DA and a non-display region NDA defined therein. The non-display region NDA may be defined along surrounding of the display region DA. The display region DA may correspond to the display region DA of the display device DD illustrated in FIG. 1. The non-display region NDA may correspond to the non-display region NDA of the display device DD illustrated in FIG. 1.

The display panel DP may include a plurality of pixels PX, a data integrated circuit DIC, a plurality of pads PD, a flexible printed circuit board FPCB, an input sensor integrated circuit TIC, and a control integrated circuit CIC.

The data integrated circuit DIC may be electrically connected to the pixels PX of the display region DA and configured to provide data signal to the pixels PX.

The input sensor integrated circuit TIC and the control integrated circuit CIC may be mounted in the flexible printed circuit board FPCB and configured to receive electronic signal from the plurality of pads PD.

The input sensor integrated circuit TIC may use the plurality of pads PD to process a signal corresponding to a change of current applied to the display area DA due to a user’s touch or a signal corresponding to an applied external pressure via the input sensor unit ISP.

The control integrated circuit CIC may be a circuit configured to control at least one of the data integrated circuit DIC and the input sensor integrated circuit TIC.

A bending region BA of the display panel DP may be bent.

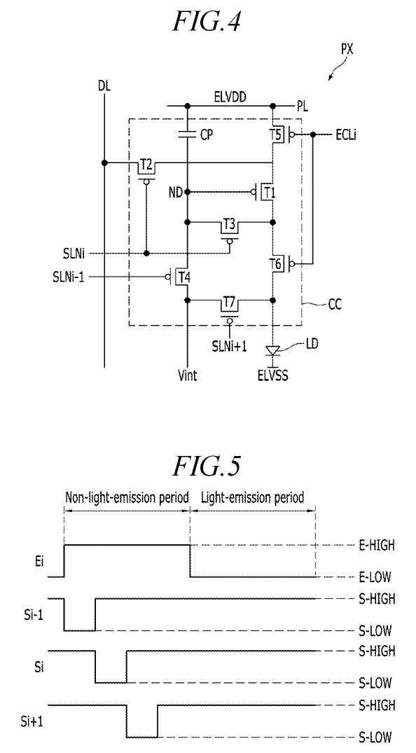

FIG. 4 illustrates an equivalent circuit of a pixel PX according to an embodiment of the present disclosure. FIG. 5 is an example illustration of light-emission control signals Ei and scan signals Si-1, Si and Si+1 applied to the pixel PX illustrated in FIG. 4. FIG. 4 is an example illustration of the pixel PX connected to an i-th scan line SLi and an i-th light-emitting control line ECLi.

The pixel PX may include a light-emitting diode LD and a pixel circuit CC. The pixel circuit CC may include a plurality of transistors T1 through T7 and a capacitor CP. The pixel circuit CC may be configured to control an amount of current flowing through the light-emitting diode LD in response to a data signal.

The light-emitting diode LD may be configured to emit light with a selectable luminance corresponding to the amount of current provided from the pixel circuit CC. To that end, a level of a first power ELVDD may be set higher than a level of a second power ELVSS.

The plurality of transistors T1 to T7 may each include an input electrode (or a source electrode), an output electrode (or a drain electrode), and a control electrode (or a gate electrode). In the present disclosure, for convenience, one of the input electrode and the output electrode may be referred to as a first electrode, and the other may be referred to as a second electrode.

The first electrode of the first transistor T1 is connected to the first power ELVDD via the fifth transistor T5, and the second electrode is connected to a first driving electrode of the light-emitting diode LD via the sixth transistor T6. The first transistor T1 may be referred to as a driving transistor in this specification.

The first transistor T1 is configured to control an amount of current flowing through the light-emitting diode LD in response to a voltage applied to the control electrode.

The second transistor T2 is connected between the data line DL and the first electrode of the first transistor T1. In some aspects, the control electrode of the second transistor T2 is connected to the i-th scan line SLi. In case that the i-th scan signal Si is provided to the i-th scan line SLi, the second transistor T2 is turned on to electrically connect the data line DL and the first electrode of the first transistor T1.

The third transistor T3 is connected between the second electrode of the first transistor T1 and the control electrode. The control electrode of the third transistor T3 is connected to the i-th scan line SL. In case that the i-th scan signal Si is provided to the i-th scan line SLi, the third transistor T3 is turned on to electrically connect the second electrode of the first transistor T1 and the control electrode. Accordingly, in case that the third transistor T3 is turned on, the first transistor T1 is connected in a form of a diode.

The fourth transistor T4 is connected between a node ND and an initialization power generation unit (not illustrated). In some aspects, the control electrode of the fourth transistor T4 is connected to the (i-1)-th scan line SLi-1. In an example in which the (i-1)-th scan signal Si-1 is provided to the (i-1)-th scan line SLi-1, the fourth transistor T4 is turned on to provide an initialization voltage Vint to the node ND.

The fifth transistor T5 is connected between a power line PL and the first electrode of the first transistor T1. The control electrode of the fifth transistor T5 is connected to the i-th light-emission control line ECLi.

The sixth transistor T6 is connected between the second electrode of the first transistor T1 and the first driving electrode of the light-emitting diode LD. In some aspects, the control electrode of the sixth transistor T6 is connected to the i-th light-emission control line ECLi.

The seventh transistor T7 is connected between the initialization power generation unit (not illustrated) and the first driving electrode of the light-emitting diode LD. In some aspects, the control electrode of the seventh transistor T7 is connected to the (i+1)-th scan line SLi+1. In case that the (i+1)-th scan signal Si+1 is provided to the (i+1)-th scan line SLi+1, such seventh transistor T7 is turned on to provide the initialization voltage Vint to the first driving electrode of the light-emitting diode LD.

The seventh transistor T7 may improve black expression capability of the pixel PX. Particularly, in case that the seventh transistor T7 is turned on, a parasitic capacitor (not illustrated) of the light-emitting diode LD is discharged. Then, in case that black luminance is implemented, the light-emitting diode LD does not emit light due to the leakage current from the first transistor T1, and accordingly, the black expression capability may be improved.

In FIG. 5, the control electrode of the seventh transistor T7 is illustrated to be connected to the (i+1)-th scan line SLi+1, but the present disclosure is not limited to this configuration. In another embodiment of the present disclosure, the control electrode of the seventh transistor T7 may be connected to the i-th scan line SLi or the (i-1)-th scan line SLi-1.

Illustration of FIG. 4 is based on PMOS, but the present disclosure is not limited to this configuration. In another embodiment of the present disclosure, the pixel PX may be composed of NMOS. In another embodiment of the present disclosure, the pixel PX may be composed of a combination of NMOS and PMOS.

The capacitor CP is disposed between the power line PL and the node ND. The capacitor CP is configured to store a voltage corresponding to the data signal. In case that the fifth transistor T5 and the sixth transistor T6 are turned on, the amount of current flowing through the first transistor T1 may be determined according to the voltage stored in the capacitor CP.

In the present disclosure, a structure of the pixel PX is not limited to what is illustrated in FIG. 4. In another embodiment of the present disclosure, the pixel PX may be implemented in various forms configured for the light-emitting diode LD to emit light.

Referring to FIG. 5, the light emission control signal Ei may have a high level E-HIGH or a low level E-LOW. The scan signals SLi-1, SLi, and SLi+1 may each have a high level S-HIGH or a low level S-LOW.

In case that the light emission control signal Ei has a high level E-HIGH, the fifth transistor T5 and the sixth transistor T6 are turned off. In case that the fifth transistor T5 is turned off, the power line PL and the first electrode of the first transistor T1 are electrically cut off. In case that the sixth transistor T6 is turned off, the second electrode of the first transistor T1 and the first driving electrode of the light-emitting diode LD are electrically cut off. Accordingly, the light-emitting diode LD does not emit light while the light emission control signal Ei having a high level E-HIGH is provided to the i-th light emission control line ECLi.

Thereafter, in case that the (i-1)-th scan signal Si-1 to be provided to the (i-1)-th scan line SLi-1 has a low level S-LOW, the fourth transistor T4 is turned on. In case that the fourth transistor T4 is turned on, the initialization voltage Vint is provided to the node ND.

In case that the i-th scan signal Si provided to the i-th scan line SLi has a low level S-LOW, the second transistor T2 and the third transistor T3 are turned on.

In case that the second transistor T2 is turned on, a data signal is provided to the first electrode of the first transistor T1. Here, since the node ND is initialized to the initialization voltage Vint, the first transistor T1 is turned on. In case that the first transistor T1 is turned on, a voltage corresponding to the data signal is provided to the node ND. Here, the capacitor CP stores a voltage corresponding to the data signal.

In case that the (i+1)-th scan signal Si+1 to be provided to the (i+1)-th scan line SLi+1 has a low level S-LOW, the seventh transistor T7 is turned on.

In case that the seventh transistor T7 is turned on, the initialization voltage Vint is provided to the first driving electrode of the light-emitting diode LD, thereby discharging the parasitic capacitor of the light-emitting diode LD.

In case that the light emission control signal Ei to be provided to the light emission control line ECLi has a low level E-LOW, the fifth transistor T5 and the sixth transistor T6 are turned on. In case that the fifth transistor T5 is turned on, the first power ELVDD is provided to the first electrode of the first transistor T1. In an example in which the sixth transistor T6 is turned on, the second electrode of the first transistor T1 and the anode electrode of the light-emitting diode LD are electrically connected. Then, the light-emitting diode LD generates light of a predetermined luminance in response to the amount of supplied current.

An organic light-emitting diode OLED may be configured to emit light with a selectable luminance corresponding to an amount of current provided from the pixel circuit CC. To that end, a level of the first power ELVDD may be set higher than a level of the second power ELVSS.

The plurality of transistors T1 to T7 may each include an input electrode (or a source electrode), an output electrode (or a drain electrode), and a control electrode (or a gate electrode). In the present disclosure, for convenience, one of the input electrode and the output electrode may be referred to as a first electrode, and the other may be referred to as a second electrode.

The first electrode of the first transistor T1 is connected to the first power ELVDD via the fifth transistor T5, and the second electrode is connected to the anode electrode of the organic light-emitting diode OLED via the sixth transistor T6. The first transistor T1 may be referred to as a driving transistor in this specification.

The first transistor T1 is configured to control an amount of current flowing through the organic light-emitting diode OLED in response to a voltage applied to the control electrode.

The second transistor T2 is connected between the data line DL and the first electrode of the first transistor T1. In some aspects, the control electrode of the second transistor T2 is connected to the i-th scan line SLi. In case that the i-th scan signal Si is provided to the i-th scan line SLi, the second transistor T2 is turned on to electrically connect the data line DL and the first electrode of the first transistor T1.

The third transistor T3 is connected between the second electrode of the first transistor T1 and the control electrode. The control electrode of the third transistor T3 is connected to the i-th scan line SL. In case that the i-th scan signal Si is provided to the i-th scan line SLi, the third transistor T3 is turned on to electrically connect the second electrode of the first transistor T1 and the control electrode. Accordingly, in case that the third transistor T3 is turned on, the first transistor T1 is connected in a form of a diode.

The fourth transistor T4 is connected between a node ND and an initialization power generation unit (not illustrated). In some aspects, the control electrode of the fourth transistor T4 is connected to the (i-1)-th scan line SLi-1. In an example in which the (i-1)-th scan signal Si-1 is provided to the (i-1)-th scan line SLi-1, the fourth transistor T4 is turned on to provide an initialization voltage Vint to the node ND.

The fifth transistor T5 is connected between a power line PL and the first electrode of the first transistor T1. The control electrode of the fifth transistor T5 is connected to the i-th light-emission control line ECLi.

The sixth transistor T6 is connected between the second electrode of the first transistor T1 and the anode electrode of the organic light-emitting diode OLED. In some aspects, the control electrode of the sixth transistor T6 is connected to the i-th light-emission control line ECLi.

The seventh transistor T7 is connected between the initialization power generation unit (not illustrated) and the anode electrode of the organic light-emitting diode OLED. In some aspects, the control electrode of the seventh transistor T7 is connected to the (i+1)-th scan line SLi+1. In case that the (i+1)-th scan signal Si+1 is provided to the (i+1)-th scan line SLi+1, such seventh transistor T7 is turned on to provide the initialization voltage Vint to the anode electrode of the organic light-emitting diode OLED.

The seventh transistor T7 may improve black expression capability of the pixel PX. Particularly, in case that the seventh transistor T7 is turned on, a parasitic capacitor (not illustrated) of the organic light-emitting diode OLED is discharged. Then, in case that black luminance is implemented, the organic light-emitting diode OLED does not emit light due to the leakage current from the first transistor T1, and accordingly, the black expression capability may be improved.

In some aspects, in FIG. 4, the control electrode of the seventh transistor T7 is illustrated to be connected to the (i+1)-th scan line SLi+1, but the present disclosure is not limited to this configuration. In another embodiment of the present disclosure, the control electrode of the seventh transistor T7 may be connected to the i-th scan line SLi or the (i-1)-th scan line SLi-1.

Illustration of FIG. 4 is based on PMOS, but the present disclosure is not limited to this configuration. In another embodiment of the present disclosure, the pixel PX may be composed of NMOS. In another embodiment of the present disclosure, the pixel PX may be composed of a combination of NMOS and PMOS.

The capacitor CP is disposed between the power line PL and the node ND. The capacitor CP is configured to store a voltage corresponding to the data signal. In case that the fifth transistor T5 and the sixth transistor T6 are turned on, the amount of current flowing through the first transistor T1 may be determined according to the voltage stored in the capacitor CP.

In the present disclosure, a structure of the pixel PX is not limited to what is illustrated in FIG. 4. In another embodiment of the present disclosure, the pixel PX may be implemented in various forms configured for the organic light-emitting diode OLED to emit light.

Referring to FIG. 5, the light emission control signal Ei may have a high level E-HIGH or a low level E-LOW. The scan signals SLi-1, SLi, and SLi+1 may each have a high level S-HIGH or a low level S-LOW.

In case that the light emission control signal Ei has a high level E-HIGH, the fifth transistor T5 and the sixth transistor T6 are turned off. In case that the fifth transistor T5 is turned off, the power line PL and the first electrode of the first transistor T1 are electrically cut off. In case that the sixth transistor T6 is turned off, the second electrode of the first transistor T1 and the anode electrode of the organic light-emitting diode OLED are electrically cut off. Accordingly, the organic light-emitting diode OLED does not emit light while the light emission control signal Ei having a high level E-HIGH is provided to the i-th light emission control line ECLi.

Thereafter, in case that the (i-1)-th scan signal Si-1 to be provided to the (i-1)-th scan line SLi-1 has a low level S-LOW, the fourth transistor T4 is turned on. In case that the fourth transistor T4 is turned on, the initialization voltage Vint is provided to the node ND.

In case that the i-th scan signal Si provided to the i-th scan line SLi has a low level S-LOW, the second transistor T2 and the third transistor T3 are turned on.

In case that the second transistor T2 is turned on, a data signal is provided to the first electrode of the first transistor T1. Here, since the node ND is initialized to the initialization voltage Vint, the first transistor T1 is turned on. In case that the first transistor T1 is turned on, a voltage corresponding to the data signal is provided to the node ND. Here, the capacitor CP stores a voltage corresponding to the data signal.

In case that the (i+1)-th scan signal Si+1 to be provided to the (i+1)-th scan line SLi+1 has a low level S-LOW, the seventh transistor T7 is turned on.

In case that the seventh transistor T7 is turned on, the initialization voltage Vint is provided to the anode electrode of the organic light-emitting diode OLED, thereby discharging the parasitic capacitor of the organic light-emitting diode OLED.

In case that the light emission control signal Ei to be provided to the light emission control line ECLi has a low level E-LOW, the fifth transistor T5 and the sixth transistor T6 are turned on. In case that the fifth transistor T5 is turned on, the first power ELVDD is provided to the first electrode of the first transistor T1. In an example in which the sixth transistor T6 is turned on, the second electrode of the first transistor T1 and the anode electrode of the organic light-emitting diode OLED are electrically connected. Then, the organic light-emitting diode OLED generates light of a predetermined luminance in response to the amount of supplied current.

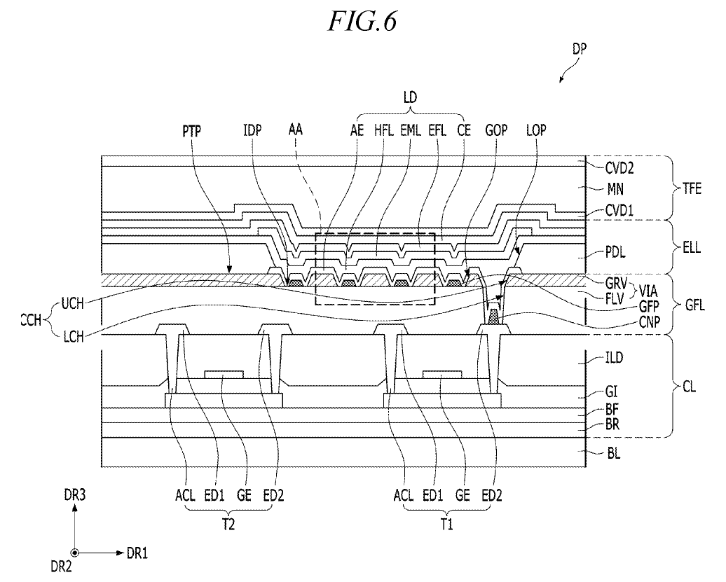

FIG. 6 is an example cross-sectional view of a display panel DP according to an embodiment of the present disclosure.

Referring to FIG. 6, the display panel DP may include a base member BL, a circuit layer CL, a grooved formation layer GFL, a light-emitting diode layer ELL, and an encapsulation layer TFE.

The base member BL may be a basis of the display panel DP. That is, other elements of the display panel DP may be laminated onto the base member BL. The base member BL may include an organic layer and/or an inorganic layer. The organic layer may include an organic material. For example, polyimide may be included. The inorganic layer may include an inorganic material.

The circuit layer CL may include a barrier layer BR, a buffer layer BF, a gate insulating layer GI, an interlayer insulating layer ILD, a first transistor T1, and a second transistor T2. The circuit layer CL may be disposed on the base member BL.

The first transistor T1 and the second transistor T2 may be configured to transfer electric signals. In some aspects, the first transistor T1 and the second transistor T2 may include a plurality of active parts ACL, a plurality of first electrodes ED1, a plurality of control electrodes GE and a plurality of second electrodes ED2.

The barrier layer BR may be disposed on the base member BL. The barrier layer BR may be configured to prevent penetration of, for example, moisture introduced from the outside. The barrier layer BR may include an inorganic insulating material, such as silicon oxide and silicon nitride.

The buffer layer BF may be disposed on the barrier layer BR. The buffer layer BF may be configured to prevent the transfer of impurities introduced from below to above. Accordingly, an element disposed on the buffer layer BF may be protected. The buffer layer BF may include an inorganic insulating material, such as silicon oxide and silicon nitride.

The plurality of active parts ACL may be disposed on the buffer layer BF. The plurality of active parts ACL may include polysilicon or amorphous silicon. Additionally, or alternatively, the plurality of active parts ACL may include metallic oxide semiconductor. The active parts ACL may include a channel area serving as a passage through which electrons or holes may move, a first ion-doped area, and a second ion-doped area, disposed such that the channel area is between the first ion-doped area and the second ion-doped area.

The gate insulating layer GI may cover the buffer layer BF and the plurality of active parts ACL. The gate insulating layer GI may include an organic film and/or an inorganic film. The gate insulating layer GI may include a plurality of inorganic thin films. The plurality of inorganic thin films may include a silicon nitride layer and a silicon oxide layer.

The plurality of control electrodes GE may be disposed on the buffer layer BF. The plurality of control electrodes GE may overlap with the plurality of active parts ACL. In some aspects, the plurality of control electrodes GE may include molybdenum (Mo).

The interlayer insulating layer ILD may cover the gate insulating layer GI and a plurality of control electrodes GE. The interlayer insulating layer ILD may include an organic film and/or an inorganic film. The interlayer insulating layer ILD may include a plurality of inorganic thin films or organic thin films. The plurality of inorganic thin films may include a silicon nitride layer and a silicon oxide layer.

The plurality of first electrodes ED1 and a plurality of second electrodes ED2 may be disposed on the interlayer insulating layer ILD. The plurality of first electrodes ED1 and the plurality of second electrodes ED2 may be electrically connected to the plurality of active parts ACL through a plurality of contact holes defined on the interlayer insulating layer ILD. In some aspects, the plurality of first electrodes ED1 and the plurality of second electrodes ED2 may include a metal.

The groove formation layer GFL may include a circuit insulating layer VIA, a connection unit CNP, and a groove formation unit GFP. An upper surface of the groove formation layer GFL may not be planarized. The upper surface of the groove formation layer GFL may have a first groove and a second groove formed.

The circuit insulating layer VIA may include a planarized circuit insulating layer FLV and a groove circuit insulating layer GRV. The circuit insulating layer VIA may include a recessed surface IDP and a protruding surface PTP. The circuit insulating layer VIA may have a connection contact hole CCH defined therein. The circuit insulating layer VIA may be disposed on the circuit layer CL. The circuit insulating layer VIA may cover the interlayer insulating layer ILD, the plurality of first electrodes ED1, and the plurality of second electrodes ED2.

A distance between the recessed surface IDP and the base member BL may be shorter than a distance between the protruding surface PTP and the base member BL. The protruding surface PTP may not overlap with the recessed surface IDP. Accordingly, groove may be formed on the upper surface of the circuit insulating layer VIA. The groove formed by the recessed surface IDP and the protruding surface PTP may be the first groove.

The connection contact hole CCH may include a lower contact hole LCH and an upper contact hole UCH. The connection contact hole CCH may expose at least a portion of the circuit layer CL. Accordingly, the circuit layer CL and the light-emitting diode layer ELL may be electrically connected through the connection contact hole CCH.

The planarized circuit insulating layer may include an organic film and/or an inorganic film. The planarized circuit insulating layer FLV may have the lower contact hole LCH defined therein. The planarized circuit insulating layer FLV may be disposed on the circuit layer CL. An upper surface of the planarized circuit insulating layer FLV may be planarized.

The groove circuit insulating layer GRV may include an organic film and/or an inorganic film. The groove circuit insulating layer GRV may have the upper contact hole UCT and an groove opening GOP defined therein. The upper contact hole UCH may overlap with the lower contact hole LCH. A width of an upper portion of the groove opening GOP may be greater than a width of a lower portion of the groove opening GOP. The groove opening GOP may have a shape of gradually widening toward the upper portion. A shape of the groove opening GOP may have a trapezoidal shape in a cross-section.

The groove opening GOP may expose a portion of the upper portion of the planarized circuit insulating layer FLV. The portion of the planarized circuit insulating layer FLV exposed by the groove opening GOP may be a recessed surface IDP. An upper surface of the groove circuit insulating layer GRV may be a protruding surface PTP. Accordingly, the first groove may be formed by the groove circuit insulating layer GRV.

The groove circuit insulating layer GRV may be formed through dry etching. An etchable circuit insulating layer may be disposed on the planarized circuit insulating layer FLV. Dry etching may be performed on the etchable circuit insulating layer to have a groove opening GOP formed. Accordingly, the groove circuit insulating layer GRV may be formed.

FIG. 6 illustrates that two layers of circuit insulating layers VIA are laminated. However, a configuration of the circuit insulating layer VIA is not limited to what is illustrated in the figure. More layers of circuit insulating layers VIA may be laminated as desired or applicable.

The connection unit CNP may be disposed in the connection contact hole CCH. At least a portion of the connection unit CNP may be disposed in the lower contact hole LCH. The connection unit CNP may include metal. The connection unit CNP may be electrically conductive. The connection unit CNP may be electrically connected to at least any one of the plurality of transistors T1 and T2. In another embodiment of the present disclosure, the connection unit CNP may be omitted.

The groove formation unit GFP may be disposed in the groove opening GOP. The groove formation unit GFP may overlap with the recessed surface IDP. A height of the groove formation unit GFP may be less than a height of the groove circuit insulating layer GRV. A groove formed by the groove formation unit GFP may be the second groove.

An area of an upper portion of the groove formation unit GFP may be smaller than an area of a lower portion of the groove formation unit GFP. The groove formation unit GFP may have a shape of gradually narrowing toward the upper portion. The groove formation unit GFP may have a trapezoidal shape or a triangular shape in a cross-section. The shape of the groove formation unit GFP in a cross-section may include a curve. The groove formation unit GFP may include a rounded corner in a cross-section.

The groove formation unit GFP may be electrically conductive. The groove formation unit GFP may include metal. The groove formation unit GFP may include a same material as the connection unit CNP. The groove formation unit GFP and the connection unit CNP may be formed of a same material.

The groove formation unit GFP may be formed through wet etching. An etchable member may be disposed on the circuit insulating layer VIA. Wet etching may be performed on the etchable member to remove a portion of the etchable member. Accordingly, a groove formation unit GFP may be formed. In some aspects, during the formation of the groove formation unit GFP, the connection unit CNP may be formed.

The light-emitting diode layer ELL may include a pixel definition film PDL and a light-emitting diode LD. The light-emitting diode layer ELL may be configured to emit light.

The pixel defining film PDL may be disposed on a portion of the circuit insulating layer VIA. A light-emission opening LOP may be defined on another portion where the pixel definition film PDL is not disposed. In some aspects, a light-emitting diode LD may be formed in the light-emission opening LOP. The light-emission opening LOP may overlap with a groove opening GOP and the groove formation unit GFP.

The light-emitting diode LD may include an anode electrode AE, a hole functional layer HFL, a light-emission layer EML, an electron functional layer EFL, and a cathode electrode CE. The light-emitting diode LD may be configured to emit light.

The anode electrode AE may be disposed on a portion of the groove formation layer GFL. The anode electrode AE may cover the groove formation unit GFP, and at least a portion of the groove circuit insulating layer GRV. Accordingly, the anode electrode AE may have a groove according to a shape of the groove circuit insulating layer GRV and the groove formation unit GFP. The anode electrode AE may have a groove according to shapes of the first groove and the second groove.

The anode electrode AE may have at least a portion disposed in the connection contact hole CCH. The anode electrode AE may be electrically connected to any one of the plurality of second electrodes ED through the connection contact hole CCH. The anode electrode AE may be electrically connected to at least any one of the plurality of transistors T1 and T2. The anode electrode AE may be configured to receive and conduct electricity transferred from the circuit layer CL. The anode electrode AE may be configured to supply a hole.

The anode electrode AE may be a reflective electrode. The anode electrode AE may be configured to reflect at least a portion of incident light. As the anode electrode AE has a groove, the anode electrode AE may be configured to diffuse incident light. Because the anode electrode AE has grooves according to shapes of the first groove and the second groove, incident light may be more effectively diffused. The light reflected by the anode electrode AE may be incident on the cathode electrode CE.

Although FIG. 6 exemplarily illustrates a first transistor T1 and a second transistor T2, structures of the first transistor T1 and the second transistor T2 are not limited to what is illustrated in the figure. In FIG. 6, the first transistor T1 is illustrated as being in direct contact with the anode electrode AE through any of the plurality of second electrodes ED2, but this merely is a cross-sectional shape, and in fact, the first transistor T1 may be connected to the anode electrode AE through another transistor. However, the present disclosure is not limited to this configuration, and in another embodiment of the present disclosure, the first transistor T1 may make direct contact with the anode electrode AE through any of the plurality of second electrodes ED2.

The hole functional layer HFL may be disposed on the anode electrode AE. The hole functional layer HFL may be configured to support transfer of a hole generated from the anode electrode AE. For example, the hole functional layer HFL may be configured to more readily receive a hole injected from the first anode electrode AE and facilitate the transfer of the hole. The hole functional layer HFL may have a multi-layer structure. For example, a hole injection layer (not illustrated) and a hole transfer layer (not illustrated) may be further included.

The light-emission layer may be disposed on the hole functional layer HFL. The light-emission layer EML may receive electricity to emit light. The light-emission layer EML may include, for example, an organic light-emitting material or a quantum dot. Accordingly, the light-emitting diode LD may be an organic light-emitting diode or a quantum dot light-emitting diode.

The electron functional layer EFL may be disposed on the light-emission layer EML. The electron functional layer EFL may be configured to support transfer of an electron generated from the cathode electrode CE. For example, the electron functional layer EFL may be configured to more readily receive an electron injected from the cathode electrode CE and facilitate the transfer of the electron. The electron functional layer EFL may have a multi-layer structure. For example, an electron injection layer (not illustrated) and an electron transfer layer (not illustrated) may be further included.

The cathode electrode CE may be disposed on the electron functional layer EFL. The cathode electrode CE may be configured to conduct electricity. The cathode electrode CE may be configured to supply an electron.

The cathode electrode CE may be a transparent electrode. The cathode electrode CE may transmit at least a portion of incident light. The light transmitted through the cathode electrode CE may be emitted to outside of the display device DD and perceived by a user.

The cathode electrode CE may be a semi-transparent electrode. The cathode electrode CE may transmit at least a portion of incident light and have the other portion reflected. In case that the cathode electrode CE and the anode electrode AE are parallel, light may be reflected by the cathode electrode CE and the anode electrode AE to cause resonance phenomenon in the light-emitting diode LD. In case that the resonance occurs in the light-emitting diode LD, there may be difference in a wavelength and a color between light emitted in the third direction DR3, which is front direction of the display panel DP, and light emitted in a direction intersecting with the third direction DR3.

However, in an embodiment of the present disclosure, because the anode electrode AE has a groove, the cathode electrode CE may not be parallel to the anode electrode AE. Accordingly, differences in wavelengths and colors between light emitted in the third direction DR3 and light emitted in a direction intersecting with the third direction DR3 may be decreased. Therefore, color reproduction of the light emitted in a direction intersecting with the third direction DR3 may be improved.

The encapsulation layer TFE may be configured to seal the light-emitting diode LD to protect the light-emitting diode LD from external oxygen or moisture. The encapsulation layer TFE may include a first encapsulation inorganic layer CVD1, an encapsulation organic layer MN, a second encapsulation inorganic layer CVD2.

In FIG. 6, it is exemplarily illustrated that the encapsulation layer TFE includes two encapsulation inorganic layers CVD1 and CVD2 and one encapsulation organic layer MN, but embodiments of the present disclosure are not limited thereto. For example, the encapsulation layer TFE may include three encapsulation inorganic layers and two encapsulation organic layers, and in this case, the encapsulation inorganic layers and the encapsulation organic layers may be alternatingly laminated.

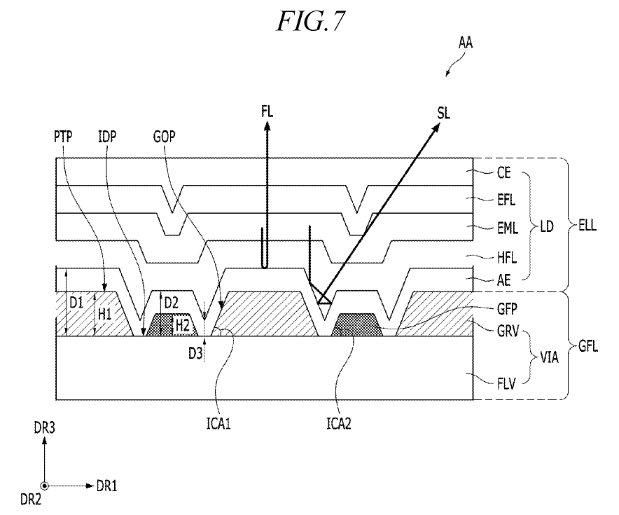

FIG. 7 is an example magnified view of the AA section illustrated in FIG. 6.

Referring to FIG. 7, light emitted from the light-emission layer EML may include front light FL and side light SL. A height of the groove circuit insulating layer GRV may be a first height H1, and a height of the groove formation unit GFP may be a second height H2. A distance between an upper surface of the anode electrode AE and an upper surface of the planarized circuit insulating layer FLV may be a first distance D1, a second distance D2, or a third distance D3. An angle between an inner side surface of the groove circuit insulating layer GRV and an upper surface of the planarized circuit insulating layer FLV may be a first inclined angle ICA1, and an angle between a side surface of the groove formation unit GFP and the upper surface of the planarized circuit insulating layer FLV may be a second inclined angle ICA2.

The front light FL and the side light SL may be a light emitted in the third direction DR3 to be incident on the anode electrode AE. The front light FL and the side light SL may be reflected to different directions by the anode electrode AE. As result, at least a portion of light emitted in the third direction DR3 to be incident on the anode electrode AE may not be reflected to the third direction DR3. Therefore, light incident on the anode electrode AE may be diffused to increase a viewing angle of the display panel DP.

The front light FL may be emitted from the light-emission layer EML to the third direction DR3 to be incident on the anode electrode AE and reflected in the third direction DR3. The front light FL may be light incident on a portion of the anode electrode AE parallel to a plane defined by the first direction DR1 and the second direction DR2. For example, the front light FL may be light incident on a portion of the anode electrode AE overlapping with the protruding surface PTP.

The side light SL may be emitted from the light-emission layer EML to the third direction DR3 to be incident on the anode electrode AE and reflected in a direction intersecting with the third direction DR3. The side light SL may be light incident on a portion of the anode electrode AE intersecting with a plane defined by the first direction R1 and the second direction DR2. For example, the side light SL may be light incident on a portion of the anode electrode AE overlapping with an inner side surface of the groove circuit insulating layer GRV. In an embodiment of the present disclosure, the side light SL may be generated to diffuse light and increase a viewing angle of the display panel DP. Therefore, luminance of light emitted in a direction intersecting with the third direction DR3 may be improved.

The first height H1 may be greater than the second height H2. Therefore, in the groove formation layer GFL, the first groove having the first height H1 and the second groove having the second height H2 may be formed. The anode electrode AE may be disposed along a shape of the groove formation layer GFL. Therefore, light incident on the anode electrode AE may be more effectively diffused.

The first distance D1 may be a distance between a portion of an upper surface of the anode electrode AE overlapping with the groove circuit insulating layer GRV and an upper surface of the planarized circuit insulating layer FLV.

The second distance D2 may be a distance between a portion of the upper surface of the anode electrode AE overlapping with the groove formation unit GFP and the upper surface of the planarized circuit insulating layer FLV. The second distance D2 may be greater than the first distance D1. Therefore, a groove may be formed on the upper surface of the anode electrode AE.

The third distance D3 may be a distance between a portion of the upper surface of the anode electrode AE not overlapping with the groove circuit insulating layer GRV or the groove formation unit GFP and the upper surface of the planarized circuit insulating layer FLV. The third distance D3 may be smaller than the first distance D1 and the second distance D2. Therefore, the upper surface of the anode electrode AE may have a trench unit formed by recession of a portion of the upper surface of the anode electrode AE. The trench unit may be positioned between the groove circuit insulating layer GRV and the groove formation unit GFP in a cross-sectional view. As the trench unit is formed on the upper surface of the anode electrode AE, light incident on the anode electrode AE may be more effectively diffused.

An inner side surface of the groove circuit insulating layer GRV may be a surface defining the groove opening GOP. The first inclined angle ICA1 may range from 20 degrees to 80 degrees. Therefore, effects of increasing a viewing angle of a display panel DP by having the groove circuit insulating layer GRV may be increased. In some aspects, the anode electrode AE and the light-emission layer EML may be uniformly disposed on the groove circuit insulating layer GRV.

In case that the first inclined angle ICA1 is smaller than 20 degrees, an angle between the side light SL reflected by the anode electrode AE and the third direction DR3 may be small. Therefore, effects of increasing a viewing angle by the side light SL may be decreased.

In case that the first inclined angle ICA1 is greater than 80 degrees, an area of the anode electrode AE overlapping with the inner side surface of the groove circuit insulating layer GRV may be decreased. Therefore, side light SL may be reduced.

In case that the first inclined angle ICA1 is greater than 80 degrees, the anode electrode AE may not be uniformly disposed on the inner side surface of the groove circuit insulating layer GRV. For example, overhanging may be caused in a portion of the anode electrode AE adjacent to the inner side surface of the groove circuit insulating layer GRV. Therefore, because a thickness of a portion of the anode electrode AE is increased, the anode electrode AE may not be uniformly disposed.

In a comparative example in which the first inclined angle ICA1 is greater than 80 degrees, the light-emission layer EML may not be uniformly disposed. For example, during deposition of the light-emission layer EML, shadow effect may be caused due to the anode electrode AE and the hole functional layer HFL. Therefore, the light-emission layer EML may not be disposed in some areas, and the light-emission layer may not be uniformly disposed.

The second inclined angle ICA2 may range from 20 degrees to 80 degrees. Therefore, effects of increasing a viewing angle of a display panel DP by the groove formation unit GFP may be increased. In some aspects, the anode electrode AE and the light-emission layer EML may be uniformly disposed on the groove formation unit GFP.

In case that the second inclined angle ICA2 is smaller than 20 degrees, an angle between side light SL reflected by the anode electrode AE and the third direction DR3 may be small. Therefore, effects of increasing a viewing angle by the side light SL may be decreased.

In a comparative example in which the second inclined angle ICA2 is greater than 80 degrees, an area of the anode electrode AE overlapping with the side surface of the groove formation unit GFP may become small. Therefore, side light SL may be reduced.

In a comparative example in which the second inclined angle ICA2 is greater than 80 degrees, the anode electrode AE may not be uniformly disposed on a side surface of the groove formation unit GFP. For example, overhanging may be caused in a portion of the anode electrode AE adjacent to the side surface of the groove formation unit GFP. Therefore, a thickness of a portion of the anode electrode AE may be increased, and the anode electrode AE may not be uniformly disposed.

In a comparative example in which the second inclined angle ICA2 is greater than 80 degrees, the light-emission layer EML may not be uniformly disposed. For example, during deposition of the light-emission layer EML, shadow effects may be caused by the anode electrode AE and the hole functional layer HFL. Therefore, the light-emission layer EML may not be disposed on some area, and the light-emission layer EML may not be uniformly disposed.

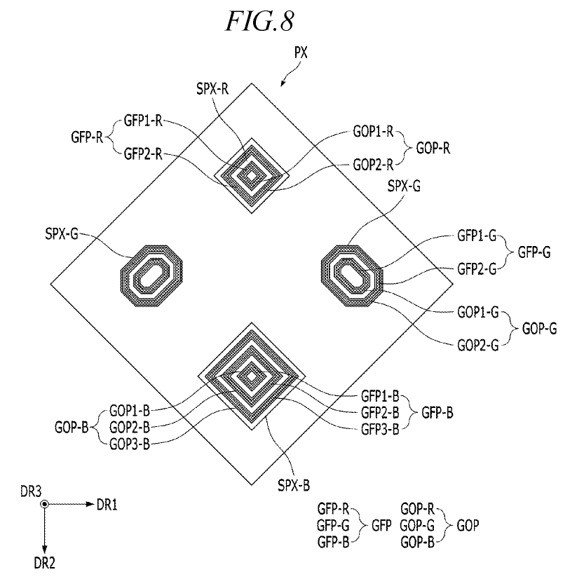

FIG. 8 is an example plan view of any one of a plurality of pixels PX according to an embodiment of the present disclosure.

Referring to FIG. 8, the pixel PX may include a red sub-pixel SPX-R, two green sub-pixels SPX-G, and a blue sub-pixel SPX-B. The groove opening GOP and the groove formation unit GFP may overlap with the plurality of sub-pixels SPX-R, SPX-G, SPX-B. The plurality of sub-pixels SPX-R, SPX-G, SPX-B may be configured to emit light in different wavelengths.

The red sub-pixel SPX-R may be configured to emit light in a first wavelength. The light in the first wavelength may be red light. The first wavelength may range from 620 nm to 750 nm.

The two green sub-pixels SPX-G may be configured to emit light in a second wavelength. The light in the second wavelength may be different the light in the first wavelength. The light in the second wavelength may be green light. The second wavelength may range from 500 nm to 570 nm.

The blue sub-pixel SPX-B may be configured to emit light in a third wavelength. The light in the third wavelength may be different from the light in the first wavelength and the light in the second wavelength. The light in the third wavelength may be blue light. The third wavelength may range from 450 nm to 500 nm.

FIG. 8 illustrates a pixel having a diamond pixel shape where the plurality of sub-pixels SPX-R, SPX-G, SPX-B are arranged in a diamond structure, but a shape of a pixel PX of the present disclosure is not limited to what is illustrated in the figure. The pixel PX of the present disclosure may be a pixel PX having a stripe pixel shape. In the pixel PX having a stripe pixel shape, the plurality of sub-pixels SPX-R, SPX-G, SPX-B may have a rectangular shape, and the plurality of sub-pixels SPX-R, SPX-G, SPX-B may be arranged. In some aspects, numbers of the red sub-pixel SPX-R, the green sub-pixels SPX-G, and blue sub-pixel SPX-B are not limited to the above descriptions.

The groove opening GOP may be provided in plurality. The plurality of groove openings GOP may include a red groove opening GOP-R, a green groove opening GOP-G, and a blue groove opening GOP-B.

The red groove opening GOP-R may overlap with the red sub-pixel SPX-R. The red groove opening GOP-R may be provided in plurality. The plurality of red groove openings GOP-R may include a first red groove opening GOP1-R, and a second red groove opening GOP2-R. The second red groove opening GOP2-R may surround the first red groove opening GOP1-R.

The green groove opening GOP-G may overlap with the green sub-pixel SPX-G. The green groove opening GOP-G may be provided in plurality. The plurality of green groove openings GOP-G may include a first green groove opening GOP1-G, and a second green groove opening GOP2-G. The second green groove opening GOP2-G may surround the first green groove opening GOP1-G.

The blue groove opening GOP-B may overlap with the blue sub-pixel SPX-B. The blue groove opening GOP-B may be provided in plurality. The plurality of blue groove openings GOP-B may include a first blue groove opening GOP1-B, a second blue groove opening GOP2-B, and a third blue groove opening GOP3-B. The second blue groove opening GOP2-B may surround the first blue groove opening GOP1-B. The third blue groove opening GOP3-B may surround the second blue groove opening GOP2-B.

Therefore, the plurality of groove openings GOP may be defined, and light emitted from the display panel DP may be more effectively diffused. In some aspects, the plurality of second groove openings GOP2-R, GOP2-G, GOP2-B may each surround any corresponding one among the plurality of first groove openings GOP1-R, GOP1-G, GOP1-B. Therefore, light emitted from the display panel DP may be more effectively diffused.

The groove formation unit GFP may be provided in plurality on a plane. The plurality of groove formation units GFP may include a red groove formation unit GFP-R, a green groove formation unit GFP-G, and a blue groove formation unit GFP-B.

The red groove formation unit GFP-R may be disposed in the red groove opening GOP-R. The red groove formation unit GFP-R may be provided in plurality. The plurality of red groove formation units GFP-R may include a first red groove formation unit GFP1-R and a second red groove formation unit GFP2-R.

The first red groove formation unit GFP1-R may be disposed in the first red groove opening GOP1-R. The second red groove formation unit GFP2-R may be disposed in the second red groove opening GOP2-R. The second red groove formation unit GFP2-R may surround the first red groove formation unit GFP1-R.

The green groove formation unit GFP-G may be disposed in the green groove opening GOP-G. The green groove formation unit GFP-G may be provided in plurality. The plurality of green groove formation units GFP-G may include a first green groove formation unit GFP1-G and a second green groove formation unit GFP2-G.

The first green groove formation unit GFP1-G may be disposed in the first green groove opening GOP1-G. The second green groove formation unit GFP2-G may be disposed in the second green groove opening GOP2-G. The second green groove formation unit GFP2-G may surround the first green groove formation unit GFP1-G.

The blue groove formation unit GFP-B may be disposed in the green groove opening GOP-B. The blue groove formation unit GFP-B may include a first blue groove formation unit GFP1-B, a second blue groove formation unit GFP2-B, and a third blue groove formation unit GFP3-B.

The first blue groove formation unit GFP1-B may be disposed in the first blue groove opening GOP1-B. The second blue groove formation unit GFP2-B may be disposed in the second blue groove opening GOP2-B. The third blue groove formation unit GFP3-B may be disposed in the third blue groove opening GOP3-B. The second blue groove formation unit GFP2-B may surround the first blue groove formation unit GFP1-B. The third blue groove formation unit GFP3-B may surround the second blue groove formation unit GFP2-B.

Accordingly, a plurality of groove formation units GFP may be disposed, and light emitted from the display panel DP may be more effectively diffused. In some aspects, the plurality of second groove formation units GFP2-R, GFP2-G, GFP2-B may each surround any corresponding one among the plurality of first groove formation units GFP1-R, GFP1-G, GFP1-B. Therefore, light emitted from the display panel DP may be more effectively diffused.

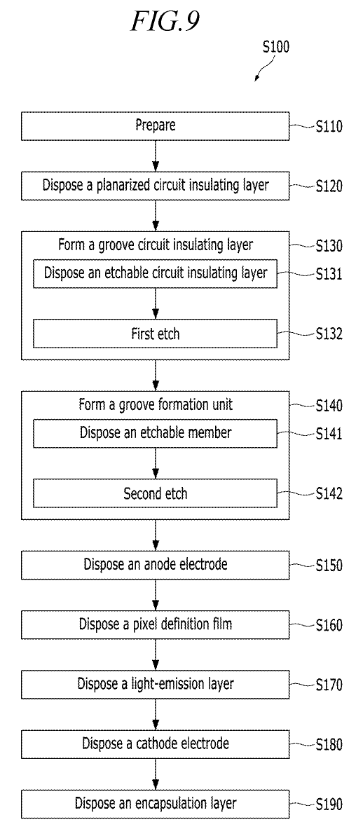

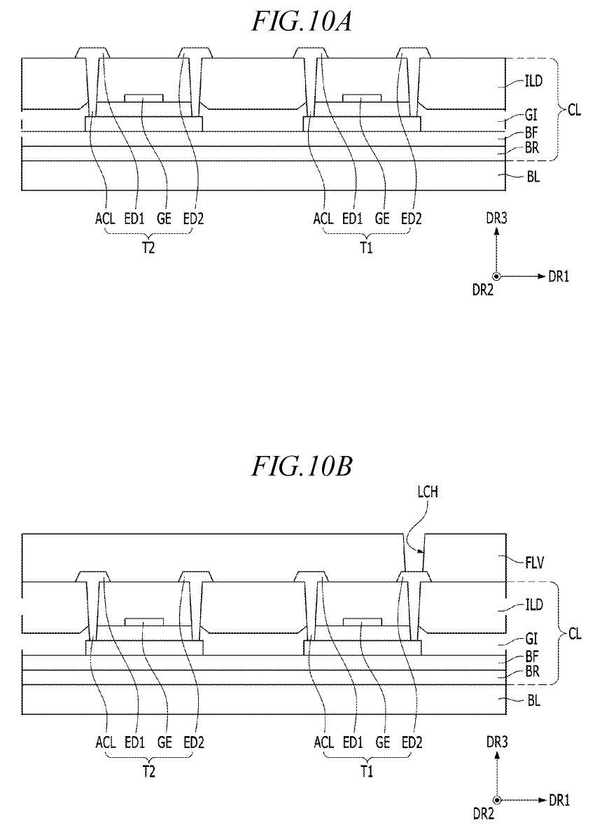

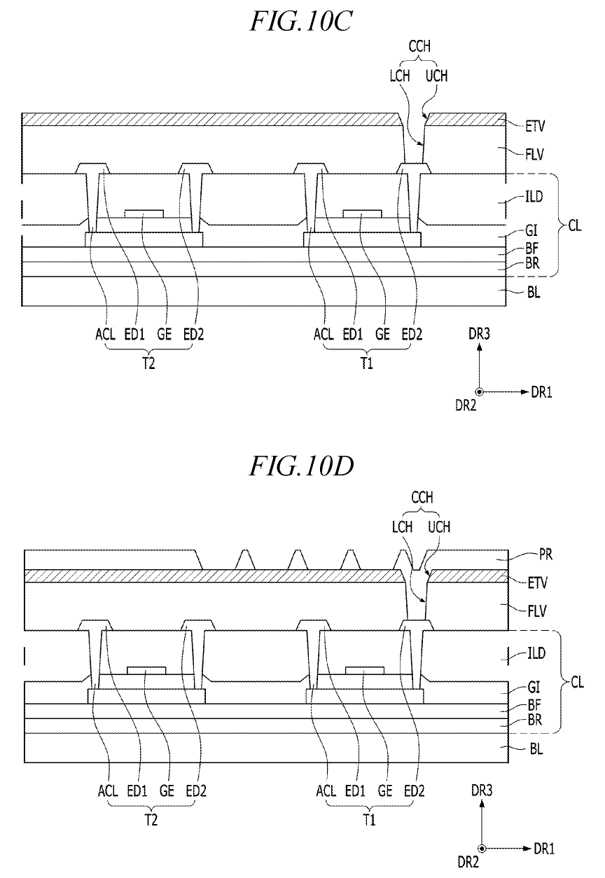

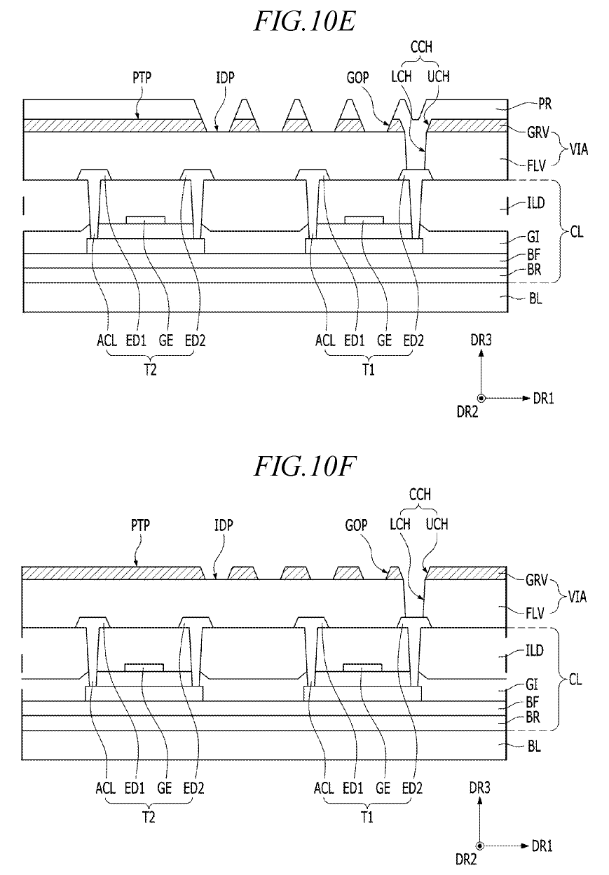

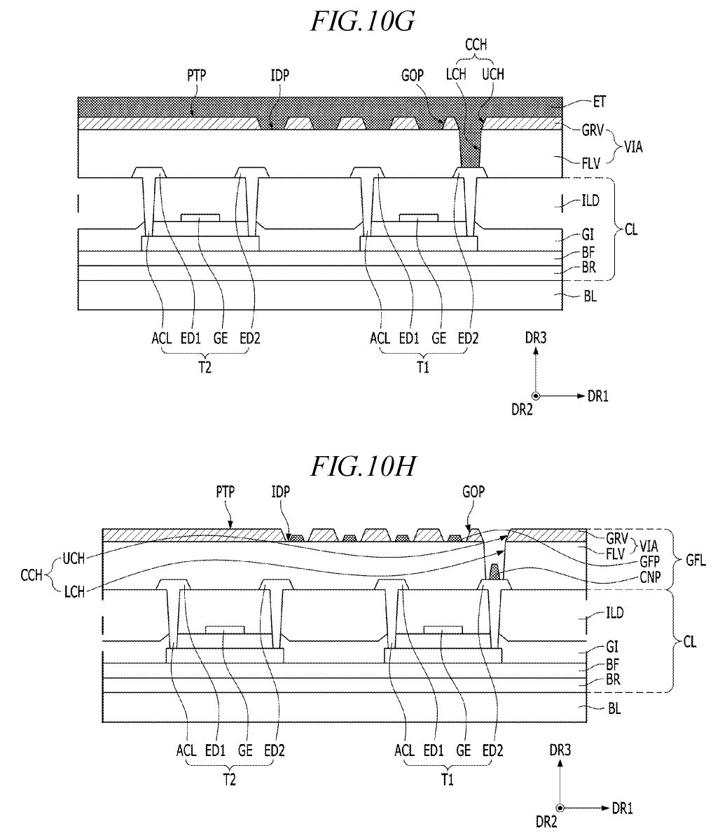

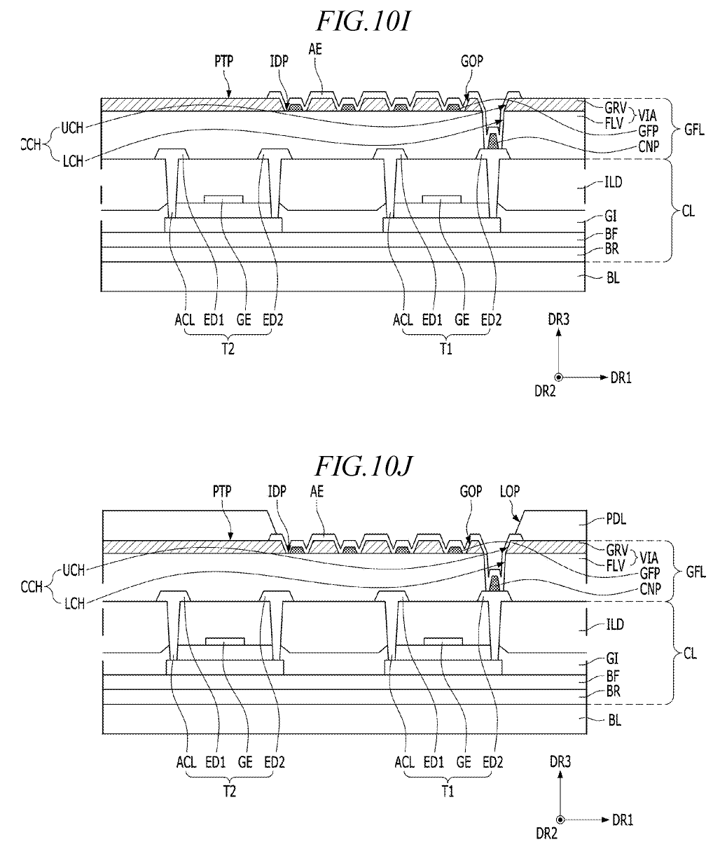

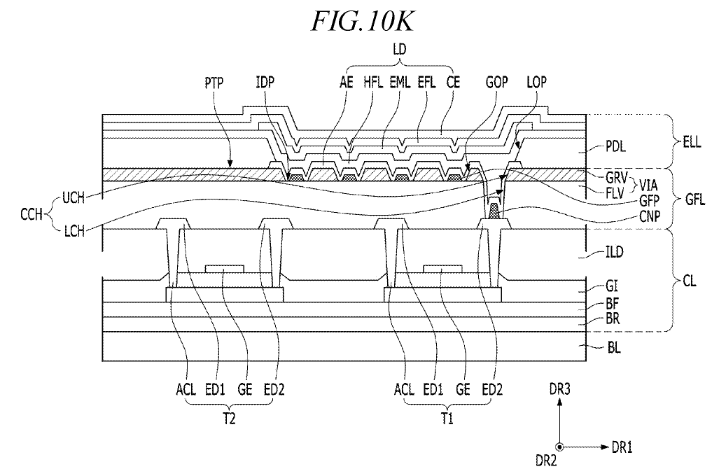

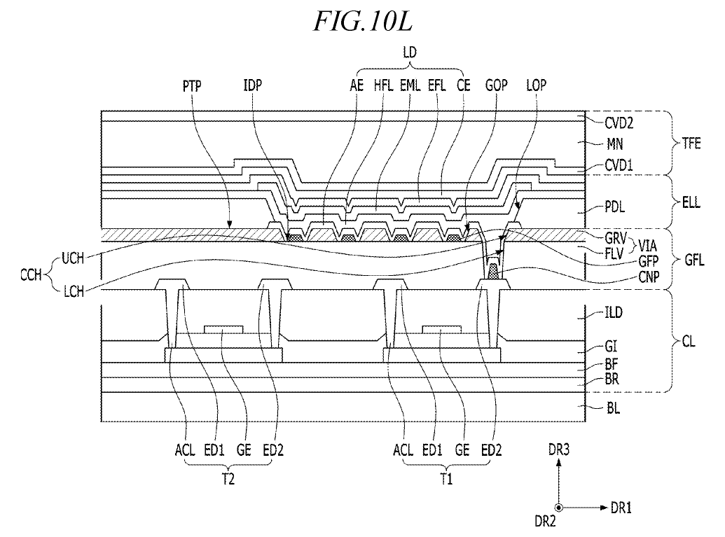

FIG. 9 is a flow chart of a method of manufacturing a display panel S100 according to an embodiment of the present disclosure. FIG. 10A through FIG. 10L each illustrates a schematic cross-section of a step of the method of manufacturing a display panel S100 according to an embodiment of the present disclosure.

Referring to FIG. 9 and FIG. 10A through FIG. 10L, a manufacturing method for an electronic device according to an embodiment of the present disclosure will be described. The same reference numerals are used for the same elements described in FIG. 1 through FIG. 9, and detailed descriptions thereof are omitted.

Referring to FIG. 9, a manufacturing method for an electronic device S100 of the present disclosure may include preparing S110, disposing a planarized circuit insulating layer S120, forming a groove circuit insulating layer S130, forming a groove formation unit S140, disposing an anode electrode S150, disposing a pixel definition film S160, disposing a light-emission layer S170, disposing a cathode electrode S180, and disposing an encapsulation layer S190.

Referring to FIG. 9 and 10A, in the preparing S110, a base member BL and a circuit layer CL may be prepared.

Referring to FIG. 9 and FIG. 10B, in the disposing a planarized circuit insulating layer S120, a planarized circuit insulating layer FLV may be disposed. A lower contact hole LCH may be defined in the planarized circuit insulating layer FLV disposed in the disposing a planarized circuit insulating layer S120.

Referring to FIG. 9 and FIG. 10C through FIG. 10F, the forming a groove circuit insulating layer S130 may include disposing an etchable circuit insulating layer S131 and performing a first etching S132. In the forming a groove circuit insulating layer S130, a groove circuit insulating layer GRV may be formed. An upper contact hole UCH may be defined in the groove circuit insulating layer GRV formed in the forming a groove circuit insulating layer S130.

Referring to FIG. 9 and FIG. 10C, an etchable circuit insulating layer ETV may be disposed in the disposing an etchable circuit insulating layer. The etchable circuit insulating layer ETV may be a subject of etching described herein. An upper contact hole UCH may be defined in the etchable circuit insulating layer ETV disposed in the disposing an etchable circuit insulating layer S131.

Referring to FIG. 9 and FIG. 10D through FIG. 10F, in the first etching S132, the etchable circuit insulating layer ETV may be etched to form a groove circuit insulating layer GRV. In FIG. 10D, a photoresistor PR may be disposed on the etchable circuit insulating layer ETV. The photoresistor PR may be disposed along the pattern. In FIG. 10E, the etchable circuit insulating layer ETV may be etched to form a groove circuit insulating layer GRV. The etchable circuit insulating layer ETV may be dry etched. In FIG. 10F, the photoresistor PR may be removed.

Referring to FIG. 9, FIG. 10G and FIG. 10H, the forming a groove formation unit S140 may include disposing an etchable member S141 and second etching S142. In the forming a groove formation unit S140, a groove formation unit GFP and a connection unit CNP may be formed.

Referring to FIG. 9 and FIG. 10G, in the disposing an etchable member S141, an etchable member ET may be disposed on the circuit insulating layer VIA. The etchable member ET may be disposed in the groove opening GOP and the connection contact hole CCH. The etchable member ET may be a subject of etching. The etchable member ET may include metal. The etchable member ET may be electrically conductive. The etchable member ET may be formed through a plating process. An upper surface of the etchable member ET may be flat.

Referring to FIG. 9 and FIG. 10H, in the second etching S142, an etchable member ET may be etched to form a groove formation unit GFP and a connection unit CNP. The etchable member ET may be wet etched. A portion of the etchable member ET disposed in the groove opening GOP may be etched to form a groove formation unit GFP. A portion of the etchable member ET disposed in the connection contact hole CCH may be etched to form a connection unit CNP.

Referring to FIG. 9 and FIG. 10I, in the disposing an anode electrode S150, an anode electrode AE may be disposed. The anode electrode AE may be disposed along shapes of the groove circuit insulating layer GRV and the groove formation unit GFP.

Referring to FIG. 9 and FIG. 10J, in the disposing a pixel definition film S160, a pixel definition film PDL may be disposed.

Referring to FIG. 9 and FIG. 10K, in the disposing a light-emission layer S170, a light-emission layer EML may be disposed. In the disposing a cathode electrode S180, a cathode electrode CE may be disposed.

Referring to FIG. 9 and FIG. 10L, in the disposing an encapsulation layer S190, an encapsulation layer TFE may be disposed.

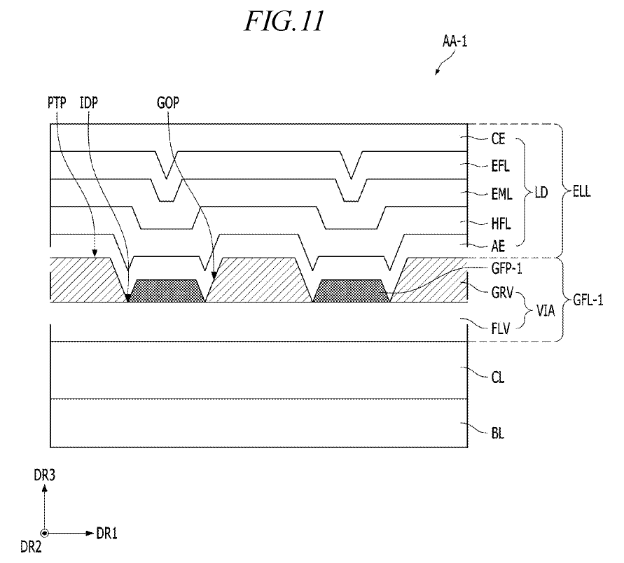

FIG. 11 is an example illustration of a magnified view of an example cross-section of a display panel DP according to an embodiment of the present disclosure.

Referring to FIG. 11, the groove formation unit GFP-1 may cover a recessed surface IDP. Even for a case in which the groove formation unit GFP-1 covers the recessed surface IDP, a first groove and a second groove may be formed on an upper surface of the groove formation layer GFL-1. Therefore, the anode electrode AE may be configured to more effectively diffuse incident light.

The groove formation unit GFP-1 in FIG. 11 may be formed by being etched for a shorter period than the groove formation GFP in FIG. 7. Even for a case in which an etching period is relatively short, the groove formation unit GFP-1 may be easily formed.

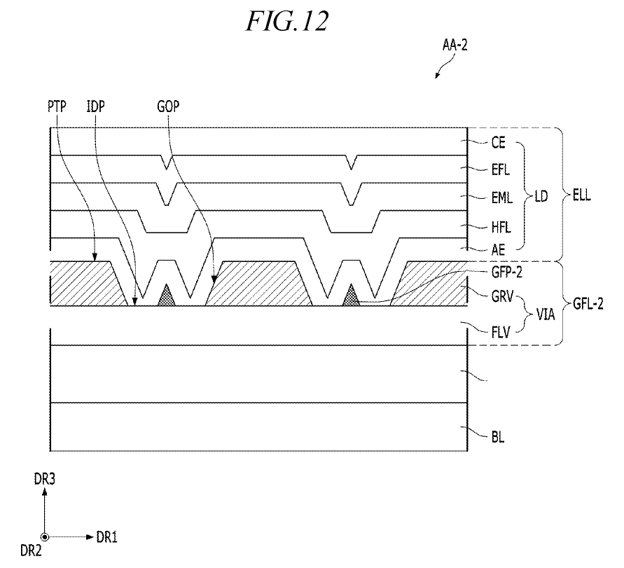

FIG. 12 is an example illustration of a magnified view of an example cross-section of a display panel DP according to an embodiment of the present disclosure.

Referring to FIG. 12, a shape of the groove formation unit GFP-2 may be triangular in a cross-section. Even in cased that a shape of the groove formation unit GFP-2 is a triangle in a cross-section, a first groove and a second groove may be formed on an upper surface of the groove formation layer GFL-2. Therefore, the anode electrode AE may be configured to more effectively diffuse incident light.

The groove formation unit GFP-2 in FIG. 12 may be formed through being etched for a longer period than the groove formation unit GFP in FIG. 7. Even for a case in which an etching period is relatively long, the groove formation unit GFP-2 may be easily formed.

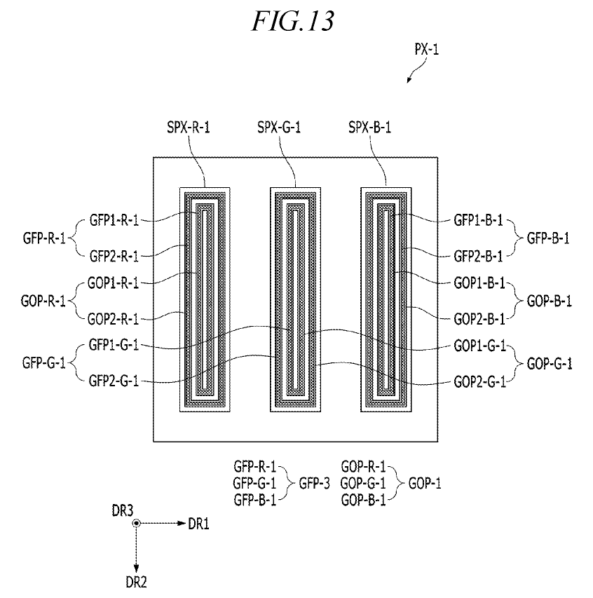

FIG. 13 is an example illustration of a plan view of any one of a plurality of pixels PX-1 according to an embodiment of the present disclosure.

Referring to FIG. 13, the pixel PX-1 may include a red sub-pixel PSX-R-1, a green sub pixel SPX-G-1, and a blue sub-pixel SPX-B_1. The groove opening GOP-1 and the groove formation unit GFP-3 may overlap with the plurality of sub-pixels SPX-R-1, SPX-G-1, SPX-B-1. The pixel PX-1 in FIG. 13 may be a pixel having a stripe pixel shape. The groove opening GOP-1 and the groove formation unit GFP-3 of the present disclosure may be applicable to pixels PX-1 of various shapes.

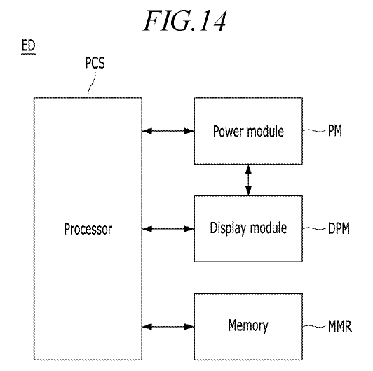

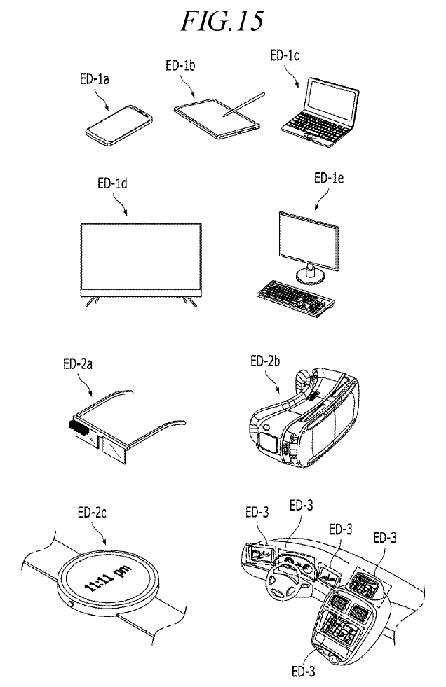

FIG. 14 is an example illustration of a block diagram of an electronic device ED according to an embodiment of the present disclosure.

Referring to FIG. 14, an electronic device ED according to an embodiment of the present disclosure may include a display module DPM, a processor PCS, a memory MMR, and a power module PM.

The processor PCS may include at least one of a central processing unit (CPU), an application processor (AP), a graphic processing unit (GPU), a communication processor (CP), an image signal processor (ISP), and a controller.

The memory MMR may be configured to store data information for operation of the processor PCS or the display module DPM. In an example in which the processor PCS executes an application stored in the memory MMR, an image data signal and/or an input control signal may be transferred to the display module DPM, which may then process the received signals and output image information through a display screen.

The power module PM may include a power supply module, such as a power adapter or a battery device, and a power conversion module configured to convert the power supplied by the power supply module into power for the operation of the electronic device ED.

At least one of the above-described components of the electronic device ED may be included within the display device DD according to the above-described embodiments. In some aspects, certain individual modules included functionally within a single module may be provided within the display device while other individual modules may be provided outside the display device. For instance, the display device may include the display module DPM, and the processor PCS, memory MMR, and power module PM may be provided as other devices within the electronic device ED but not within the display device.

FIG. 15 are example schematic diagrams of electronic devices ED according to various embodiments of the present disclosure.

Referring to FIG. 15, various electronic devices applied with a display device according to the embodiments may include not only an electronic device for displaying an image, such as a smartphone (ED-1a), a tablet PC (ED-1b), a laptop (ED-1c), a TV (ED-1d), and a desk monitor (ED-1e), but also a wearable electronic device including a display module, such as a smart glasses (ED-2a), a head-mounted display (ED-2b), and a smartwatch (ED-2c), and an electronic device for a vehicle(ED-3) including a display module, such as a dashboard of an automobile, a center fascia, CID (Center Information Display) disposed on a dashboard, and a room mirror display.

While certain embodiments of the present disclosure have been described herein, anyone ordinarily skilled in the art to which the present disclosure pertains shall appreciate that there may be a variety of modifications and permutations of the present disclosure without departing from the technical ideas and scopes of the present disclosure that are defined in the appended claims. Moreover, it shall be appreciated that the disclosed embodiments are not intended to restrict the present disclosure thereto and that every technical idea within the appended claims and their equivalents is interpreted to be included in the scope of the present disclosure.

What is claimed is:

1. A display panel comprising:
a base member;
a circuit layer disposed on the base member and comprising a transistor;
a planarized circuit insulating layer disposed on the circuit layer and having a lower contact hole defined in the planarized circuit insulating layer;
a groove circuit insulating layer disposed on the planarized circuit insulating layer and having:
an upper contact hole overlapping with the lower contact hole and defined in the groove circuit insulating layer; and
a groove opening exposing a portion of an upper surface of the planarized circuit insulating layer and defined in the groove circuit insulating layer;
a groove formation unit disposed on the groove opening;
an anode electrode covering at least a portion of the groove circuit insulating layer and the groove formation unit, having at least a portion disposed in the lower contact hole, and electrically connected to the transistor;
a light-emission layer disposed on the anode electrode; and
a cathode electrode disposed on the light-emission layer.

2. The display panel of claim 1, wherein:
the groove circuit insulating layer has a first height, and
the groove formation unit has a second height less than the first height.

3. The display panel of claim 2, wherein:
a width of an upper portion of the groove opening is greater than a width of a lower portion of the groove opening, and
an area of an upper portion of the groove formation unit is smaller than an area of a lower portion of the groove formation unit.

4. The display panel of claim 3, wherein:
a distance between a portion of an upper surface of the anode electrode overlapping with the groove circuit insulating layer and the upper portion of the planarized circuit insulating layer is a first distance,
a distance between a portion of the upper surface of the anode electrode overlapping with the groove formation unit and the upper surface of the planarized circuit insulating layer is a second distance, and
the first distance is greater than the second distance.

5. The display panel of claim 4, wherein:
a distance between a portion of the upper surface of the anode electrode not overlapping with the groove circuit insulating layer and the groove formation unit and the upper surface of the planarized circuit insulating layer is a third distance, and
the third distance is smaller than the second distance.

6. The display panel of claim 3, wherein:
an angle between an inner side surface of the groove circuit insulating layer defining the groove opening and the upper surface of the planarized circuit insulating layer ranges from 20 degrees to 80 degrees, and
an angle between a side surface of the groove formation unit and the upper surface of the planarized circuit insulating layer ranges from 20 degrees to 80 degrees.

7. The display panel of claim 3, wherein the groove formation unit comprises metal.

8. The display panel of claim 3, further comprising a connection unit having at least a portion disposed in the lower contact hole and electrically connected to the transistor.

9. The display panel of claim 8, wherein:
the groove formation unit and the connection unit each comprise metal, and
the groove formation unit and the connection unit comprise a same material.

10. The display panel of claim 3, wherein:
the groove circuit insulating layer is formed through dry etching, and
the groove formation unit is formed through wet etching.

11. The display panel of claim 3, further comprising a pixel definition film disposed on the groove circuit insulating layer, wherein a light-emission opening is defined in the pixel defining film,
wherein the groove formation unit overlaps with the light-emission opening.

12. The display panel of claim 3, wherein:
the groove opening is provided in plurality,
the plurality of groove openings comprise a first groove opening and a second groove opening surrounding the first groove opening,
the groove formation unit is provided in plurality, and
the plurality of groove formation units comprise a first groove formation unit disposed in the first groove opening and a second groove formation unit disposed in the second groove opening and surrounding the first groove formation unit.

13. The display panel of claim 3, wherein:
the anode electrode is reflects at least a portion of incident light, and
the cathode electrode transmits at least a portion of incident light.

14. A method of manufacturing a display panel comprising:
preparing a base member;
preparing a circuit layer disposed on the base member and comprising a transistor;
disposing a planarized circuit insulating layer on the circuit layer;
forming a groove circuit insulating layer on the planarized circuit insulating layer, wherein a groove opening exposing a portion of an upper surface of the planarized circuit insulating layer is defined in the groove circuit insulating layer;
forming a groove formation unit in the groove opening;
disposing an anode electrode covering at least a portion of the groove circuit insulating layer along shapes of the groove circuit insulating layer and the groove formation unit, wherein the anode electrode covers the groove formation unit;
disposing a light-emission layer on the anode electrode; and
disposing a cathode electrode on the light-emission layer.

15. The method of claim 14, wherein the forming the groove circuit insulating layer comprises:
disposing an etchable circuit insulating layer on the planarized circuit insulating layer; and
performing a first etching which forms the groove circuit insulating layer, wherein the first etching comprises dry etching the etchable circuit insulating layer.

16. The method of claim 15, wherein the forming the groove formation unit comprises:
disposing an etchable member on the planarized circuit insulating layer and the groove circuit insulating layer; and
performing a second etching which forms the groove formation unit, wherein the second etching comprises wet etching the etchable member.

17. The method of claim 16, further comprising disposing a pixel definition film on the groove circuit insulating layer, wherein a light-emission opening overlapping with the groove formation unit is defined in the pixel definition film.

18. The method of claim 16, wherein:
in the disposing the planarized circuit insulating layer, a lower contact hole is defined in the planarized circuit insulating layer,
in the forming the groove circuit insulating layer, a upper contact hole overlapping with the lower contact hole is defined in the groove circuit insulating layer,
in the disposing the etchable member, the etchable member is disposed in the lower contact hole and the upper contact hole, and
in the second etching, the wet etching of the etchable member forms a connection unit having at least a portion disposed in the lower contact hole and electrically connected to the transistor.

19. The method of claim 16, wherein the groove circuit insulating layer has a first height, and the groove formation unit has a second height smaller than the first height.

20. An electronic device comprising:
a base member;
a circuit layer disposed on the base member and comprising a transistor;
a circuit insulating layer disposed on the circuit layer and comprising a recessed surface and a protruding surface not overlapping with the recessed surface, and having a connection contact hole defined in the circuit insulating layer,
wherein a distance between the recessed surface and the base member is smaller than a distance between the protruding surface and the base member;
a groove formation unit disposed on the recessed surface;
an anode electrode covering at least a portion of the circuit insulating layer and the groove formation unit, having at least a portion disposed in the connection contact hole, and electrically connected to the transistor;
a light-emission layer disposed on the anode electrode; and
a cathode electrode disposed on the light-emission layer.
